(19) United States
(12) Patent Application Publication
(10) Pub. No.: US 2014/0272198 A1
(43) Pub. Date: Sep. 18, 2014

(54) SYSTEMS, METHODS, AND MEDIA FOR CREATING METALLIZATION FOR SOLAR CELLS

(71) Applicants: Stuart Bowden, Tempe, AZ (US); Mikhael Reginevich, Brest (BY); Stanislau Herasimenka, Tempe, AZ (US)

(72) Inventors: Stuart Bowden, Tempe, AZ (US); Mikhael Reginevich, Brest (BY); Stanislau Herasimenka, Tempe, AZ (US)

(21) Appl. No.: 14/216,211

(22) Filed: Mar. 17, 2014

Related U.S. Application Data
(60) Provisional application No. 61/801,926, filed on Mar. 15, 2013.

(51) Int. Cl. H01L 31/18; C23C 14/14; C23C 14/54

(52) U.S. Cl. CPC H01L 31/18; C23C 14/54; C23C 14/14
USPC 427/597; 118/697

(57) ABSTRACT

Systems, methods, and media for forming metallization for solar cells are provided. In some embodiments, a system for forming metallization on a substrate is provided, the system comprising: a first laser; a second laser; and a hardware processor programmed to: rotate a target at a predetermined speed; cause the first laser to emit a laser pulse that causes a material to be ablated from the rotating target toward a surface of a substrate; causing a continuous laser beam emitted by the second laser to pass through the ablated material and heat clusters in ablated material prior to the clusters landing on the surface of the substrate; and causing the continuous laser beam to heat deposited clusters from the plume of ablated material that have landed on the surface of the substrate to form a metallization line.

### CROSS-REFERENCE TO RELATED APPLICATION

This application claims the benefit of U.S. Provisional Patent Application No. 61/801,926, filed Mar. 15, 2013, which is hereby incorporated by reference herein in its entirety.

### TECHNICAL FIELD

The disclosed subject matter relates to systems, methods, and media for forming metallization for solar cells.

### BACKGROUND

Metallization layers on a solar cell are typically formed by screen printing silver-containing paste onto the solar cell. This process does not allow for the forming of lines that are less than approximately 80 micrometers wide which can decrease the efficiency of the solar cell by obstructing the energy producing area. This process can also cause mechanical pressure to be applied to the substrate of the solar cell which can reduce yields by causing cracking and breakage. Additionally, as silver prices rise, the cost of producing solar cells using this process increase the overall costs of cell production.

Accordingly, it is desirable to provide new systems, methods, and media for forming metallization for solar cells.

### SUMMARY

In accordance with various embodiments of the disclosed subject matter, systems, methods, and media for forming metallization for solar cells are provided.

In accordance with some embodiments of the disclosed subject matter, a system for forming metallization on a substrate is provided, the system comprising: a first laser; a second laser; and at least one hardware processor programmed to: cause a rotating target to rotate at a predetermined speed; cause the first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target; causing a continuous laser beam emitted by the second laser to be aimed toward a first location on the surface of the substrate such that the continuous laser beam passes through the plume of ablated material and heats clusters in the plume of ablated material prior to the clusters landing on the surface of the substrate; and causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

In accordance with some embodiments of the disclosed subject matter, a method for forming metallization on a substrate is provided, the method comprising: causing a rotating target to rotate at a predetermined speed; causing a first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target; causing a continuous laser beam emitted by a second laser to be aimed toward a first location on the surface of the substrate such that the continuous laser beam passes through the plume of ablated material and heats clusters in the plume of ablated material prior to the clusters landing on the surface of the substrate; and causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

In accordance with some embodiments of the disclosed subject matter, a non-transitory computer-readable medium containing computer executable instructions that, when executed by a processor, cause the processor to perform a method for forming metallization on a substrate is provided, the method comprising: causing a rotating target to rotate at a predetermined speed; causing a first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target; causing a continuous laser beam emitted by a second laser to be aimed toward a first location on the surface of the substrate such that the continuous laser beam passes through the plume of ablated material and heats clusters in the plume of ablated material prior to the clusters landing on the surface of the substrate; and causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

In accordance with some embodiments of the disclosed subject matter, a system for forming metallization on a substrate is provided, the system comprising: a first laser; a second laser; means for causing a rotating target to rotate at a predetermined speed; means for causing the first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target; means for causing a continuous laser beam emitted by the second laser to be aimed toward a first location on the surface of the substrate such that the continuous laser beam passes through the plume of ablated material and heats clusters in the plume of ablated material prior to the clusters landing on the surface of the substrate; and means for causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

In some embodiments, the system comprises means for causing a moving platform to which the substrate is secured to advance the substrate along a direction of travel of the laser pulse.

In some embodiments, the first laser is a Nd:YAG laser and the laser pulse includes 355 nm light.

In some embodiments, the rotating target includes copper.

In some embodiments, the continuous laser beam includes 1064 nm light.

In some embodiments, the system further comprises: a rotatable mirror; and means for causing the rotatable mirror to rotate between a first position that causes the continuous laser beam to be aimed at the first location and a second position that causes the continuous laser beam to be aimed at the second location.

In some embodiments, the system further comprises: means for causing the continuous laser beam emitted by the second laser to be aimed toward a third location on the surface of the substrate having a dielectric layer such that the dielectric layer is removed prior to ablated material being deposited at the third location; and means for causing the continuous laser beam emitted by the second laser to be aimed toward a fourth location on the surface of the substrate where the dielectric layer has been removed and prior to ablated material being deposited at the fourth location such that surface of the substrate is heated at the fourth location prior to ablated material being deposited at the fourth location.

In some embodiments, the clusters that are deposited on the surface of the substrate include clusters that are between 100 nanometer and 1 micrometer in size.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example of a system for forming metallization for solar cells in accordance with some embodiments of the disclosed subject matter.

FIG. 2 shows a generalized schematic diagram of an illustrative control system suitable for implementation of the mechanisms described herein for forming metallization for solar cells in accordance with some embodiments of the disclosed subject matter.

FIG. 3 shows an example of a plume being formed when at least one pulse impinges upon a surface of rotating target in accordance with some embodiments of the disclosed subject matter.

FIG. 4 shows an example of various stages in a process for forming metallization for solar cells in accordance with some embodiments of the disclosed subject matter.

FIG. 5 shows an example of a process for forming metallization for solar cells in accordance with some embodiments of the disclosed subject matter.

FIG. 6 shows an example of a system for simultaneously forming multiple metallization fingers for solar cells in accordance with some embodiments of the disclosed subject matter.

FIG. 7 illustrates an example of hardware that can be used to implement system controller and/or any or all of controllers depicted in FIG. 2 in accordance with some embodiments of the disclosed subject matter.

### DETAILED DESCRIPTION

In accordance with various embodiments, mechanisms (which can include systems, methods, and/or media) for forming metallization for solar cells are provided.

In some embodiments, the mechanisms described herein can form a metal contact of a solar cell using laser deposition techniques. A substrate of a solar cell, which can be coated with a dielectric anti-reflection coating can be positioned under a rotating metal target, in some embodiments. The substrate can be any suitable substrate for forming a solar cell, such as crystalline silicon. Although the mechanisms described herein are generally discussed in connection with certain materials and solar cells, the mechanisms described herein can be used to deposit a wide variety of metals onto any suitable substrate with changes made to account for the properties of the different materials to be deposited and/or the properties of the substrate.

In some embodiments, the metal target includes the material that is to be deposited onto the substrate. For example, the metal target can be a disk or elongate cylinder of copper or nickel. In some embodiments, a pulse from a pulsed laser can be emitted toward the metal target and can impinge the metal target at a location above the substrate. The radiation in the laser pulse can cause sputtering (or ablation) of material from the metal target, which causes sputtered (or ablated) clusters of material to be ejected normal to the surface of the target at the location at which the ablation occurred.

In some embodiments, as described below in connection with FIG. 4, the metal target can be rotated in order to cause the larger clusters that are ablated from the target to predominantly fall onto the solar cell in a plume. These larger clusters can remain relatively hot as they descend to the surface of the solar cell and are less affected by atmospheric resistance than smaller clusters. A continuous laser can then be used to melt the still hot clusters that were ablated from the metal target into a line on the solar cell. Using the mechanisms described herein, a line that is on the order of thirty micrometers can be quickly and efficiently formed on the surface of a solar cell without the need for performing the process in a vacuum chamber.

Turning to FIG. 1, an example 100 of a system for forming metallization for solar cells is shown in accordance with some embodiments of the disclosed subject matter. In some embodiments, system 100 can include a first laser 102 that emits pulses 104 toward a rotating target 106. In some embodiments, rotating target 106 can be secured to a spindle, or any other suitable device that provides rotation of the target. First laser 102 can include any suitable laser light source that emits pulses 104 at any suitable wavelength of light. In some embodiments, a wavelength at which first laser 102 emits pulses 104 can be a wavelength suitable for ablating a material or materials to be used in rotating target 106. For example, first laser 102 can be a Nd:YAG (neodymium-doped yttrium aluminum garnet; Nd:Y₃Al₅O₁₂) laser that emits pulses 104 including light having a wavelength of 355 nanometers (nm), which can cause ablation of rotating target 106 in cases where rotating target 106 includes copper (Cu). In some embodiments, ablation of rotating target 106 caused by pulses 104 emitted by first laser 102 can cause a plume (or torch) 108 of ablated (or sputtered) material to be expelled from rotating target 106. As described below in connection with FIG. 3, the ablated material can be expelled due to absorption of radiation from pulse 104 by rotating target 106, which can lead to ionization of the material included in rotating target 106 at a particular depth below a surface of rotating target 106 (e.g., at location 302 as shown in and described in connection with FIG. 3). In one particular example, pulses 104 can be focused at a depth of one to two micrometers below the surface. Note that pulses 104 can be focused at any suitable depth below the surface of rotating target 106 to produce plume 108 having suitable characteristics. This ionization can cause the formation of a vapor-gas channel and explosive ablation of the material included in rotating target 106.

In some embodiments, for example, as described below in connection with FIG. 2, characteristics of plume 108 such as a shape of plume 108, a composition of plume 108 (e.g., a distribution of the sizes of clusters), and/or a direction of plume 108 can be controlled and/or determined based on various properties of system 100. For example, properties of system 100 which can control and/or determine characteristics of plume 108 can include: a duration of pulses 104; an angle of incidence at which pulses 104 impinge on a surface of rotating target 106 (e.g., with respect to normal at the location at which pulses 104 impinge rotating target 106); a rotational speed of rotating target 106; a radius of rotating target 106; the pressure and composition of the atmosphere in which the ablation is occurring; a temperature of rotating target 106; electrical fields and/or magnetic fields; and/or any other suitable properties of system 100 and/or rotating target 106.

In some embodiments, system 100 can include first optics 110 that are suitable to focus pulses 104 at a particular distance from first optics 110. As described below in connection with FIGS. 2 and 3, first optics 110 can be controlled and/or positioned such that pulses 104 are focused at a particular depth with respect to the surface of rotating target 108. In some embodiments, any suitable technique or techniques can be used to determine a suitable focal length and/or position for first optics 110 in order to provide focus of pulses 104 at the particular depth. For example, a distance at which pulses 104 are focused by first optics 110 can be set prior to using system 100 (e.g., by a technician or other operator of system 100 and/or automatically by a controller of system 100) and/or can be controlled during operation of system 100. In some embodiments, a focal length of first optics 110 and/or a distance at which pulses 104 are focused by first optics 110 can be set based on observed properties of system 100 and/or rotating target 106. As another example, a focal length of first optics 110 can be set and/or adjusted based on feedback from one or more sensors (e.g., as described below in connection with FIG. 2) that provide information indicative of whether pulses 104 are focused at the particular depth.

In some embodiments, a substrate 112 onto which the ablated material from rotating target 106 is to be deposited can be positioned beneath rotating target 106. Additionally, in some embodiments, substrate 112 can be affixed to a moving table or other movable platform (not shown). In some embodiments, any suitable technique or combination of techniques can be used to secure substrate 112 to the movable platform such as by using a vacuum sample holder, adhesive, clamps, any other suitable technique, or any suitable combination of techniques. In some embodiments, a path of pulses 104 from first optics 110 to a location at which pulses impinge rotating target 106 can be substantially parallel to a surface of substrate 112.

In some embodiments, a distance between a surface of substrate 112 and the location at which pulses 104 impinge on the surface of rotating target 106 can be set and/or adjusted based on a size of a feature or features to be created on substrate 112 (e.g., a width of a line of material to be deposited), one or more characteristics of plume 108, one or more materials that make up rotating target 106, and/or any other suitable properties and/or characteristics of system 100.

In some embodiments, a surface of substrate 112 and the location at which pulses 104 impinge on the surface of rotating target 106 can be set to and/or adjusted to be about 5 centimeters for depositing a thirty (30) micrometer (μm) line on substrate 112 with a rotating target made of copper and where pulses 104 emitted by first laser 102 are ultrahigh power femtoseconds pulses.

In some embodiments, system 100 can include a second laser 114 that can be used in depositing material ablated from rotating target 106. Additionally, in some embodiments, second laser 114 can be a continuous laser. For example, second laser 114 can be a continuous laser that emits light in the infrared portion of the spectrum, such as at 1064 nanometers (nm). In a more particular example, second laser 114 can be a diode-pumped solid state laser, such as a neodymium-doped yttrium orthovanadate (Nd:YVO₄) laser that produces 1064 nm light. As another more particular example, second laser 114 can be a fiber laser that produces a laser at the appropriate wavelength, and any suitable power. As yet another more particular example, second laser 114 can be a laser that emits light in the green portion of the spectrum, such as at 808 nm. In some embodiments, second laser 114 can have a power suitable for performing particular actions (e.g., as described below in connection with FIGS. 3-5). For example, second laser 114 can have a power of about 10 Watts. As another example, the power of second laser 114 can be tunable from about one Watt to about 150 Watts, and can be tuned to a particular power based on the action to be performed and/or the material on which the action is to be performed.

As described below in connection with FIGS. 3-5, second laser 114 can perform multiple functions in system 100. For example, second laser 114 can heat substrate 112 prior to deposition of ablated material 106 to prepare the substrate for deposition. As another example, second laser 114 can maintain the temperature of clusters in the ablated material from target 106 above a position at which the clusters are to be deposited. As yet another example, second laser 114 can melt the clusters together in a deposit area to increase the conductivity of a line of deposited material as compared to a line where the clusters are not melted by second laser 114.

In some embodiments, as described below in connection with FIG. 4, a beam 116 emitted by second laser 114 can be focused on a particular location of a surface of substrate 112 using second optics 118 and/or a flying mirror 120. In some embodiments, second optics 118 can include any optics that are suitable to focus beam 116 at a particular distance from second optics 118, such as a long focus lens, a diaphragm, and/or any other suitable optical components. As described below in connection with FIGS. 2 and 3, second optics 118 can be controlled and/or positioned such that beam 116 has a particular size (e.g., a particular shape and/or dimensions) at a surface of substrate 112. In some embodiments, any suitable technique or techniques can be used to determine a suitable focal length and/or position for second optics 118 in order to provide focus of beam 116 at the particular location on substrate 112 and/or having the particular size. For example, a distance at which beam 116 is focused by second optics 118 can be set prior to using system 100 (e.g., by a technician or other operator of system 100 and/or automatically by a controller of system 100) and/or can be controlled during operation of system 100. In some embodiments, a focal length of second optics 118 and/or a distance at which beam 116 is focused by second optics 118 can be set based on observed properties of system 100 and/or substrate 112. As another example, a focal length of second optics 118 can be set and/or adjusted based on feedback from one or more sensors (e.g., as described below in connection with FIG. 2) that provide information indicative of whether beam 118 is a suitable size and/or is focused at a suitable location. In some embodiments, as described below in connection with FIG. 4, second optics 118 can focus beam 116 as an elliptical spot 122 at a surface of substrate 112.

In some embodiments, flying mirror 120 and/or second optics 118 can be controlled (e.g., as described in connection with FIG. 2) to aim elliptical spot 122 at a particular location on the surface of substrate 112, on ablated material deposited on substrate 112, and/or on any other suitable material on or near substrate 112. For example, an angle between flying mirror 120 and a direction from which second laser 114 emits beam 116 can be controlled to aim elliptical spot 122. Although flying mirror 120 is described as controlling a location of elliptical spot 122, any suitable technique or combination of techniques can be used to control a direction of beam 116 and a location of elliptical spot 122 on the surface of substrate 112.

In some embodiments, material ablated from rotating target 106 by system 100 can fall toward an area of substrate 112 determined by the characteristics of plume 108. Additionally, in some embodiments, prior to receiving the ablated material in plume 108, an area of substrate 112 onto which the ablated material is to be deposited on can be preheated using second laser 114. For example, flying mirror 120 can be controlled to aim elliptical spot 122 at one or more areas of substrate 112 that are to receive ablated material from rotating target 106.

In some embodiments, flying mirror 120 can be controlled to aim elliptical spot 122 at a location on substrate through which clusters in plume 108 pass when falling onto substrate 112. For example, beam 116 focused to elliptical spot 122 by second optics 118 can be aimed and/or scanned such that clusters in plume 108 are maintained at an elevated temperature while falling to substrate 112 (e.g., close to a deposition temperature).

In some embodiments, flying mirror 120 can be controlled to aim elliptical spot 122 at ablated clusters that have fallen to the surface of substrate 112. For example, clusters that have fallen to the surface of substrate 112 can be heated to form a line 124 on substrate 112. In some embodiments, line 124 can be a line that includes at least material ablated from rotating target 106, such as copper. In some embodiments, characteristics of line 124 such as the height of line 124, the width of line 124, the aspect ratio of line 124 (e.g., the height as compared to width), the conductivity of line 124, and/or any other suitable characteristics, can depend on the properties of system 100 and/or rotating target 106. For example, the width of line 124 can depend on the width of elliptical spot 122 (e.g., as described below in connection with FIG. 4). As another example, the aspect ratio of line 124 can depend on the width of elliptical spot 122 and the amount of material deposited by ablation from rotating target 106. In a more particular example, the aspect ratio of line 124 can be increased by depositing more material ablated from rotating target 106 in a particular area (e.g., by repeatedly ablating material at the same location, by moving substrate 112 more slowly under rotating target 106, increasing a power of laser pulses 104, and/or using any other suitable technique of combination of techniques).

FIG. 2 shows a generalized schematic diagram of an illustrative control system 200 suitable for implementation of the mechanisms described herein for forming metallization for solar cells in accordance with some embodiments of the disclosed subject matter.

In some embodiments, control system 200 can include a system controller 202 that controls one or more subsystems (e.g., subsystems of system 100), receives inputs, and/or coordinates the function of the system (e.g., overall functions of system 100). As shown in FIG. 2, system controller 202 can be in communication with one or more controllers 204-216 and can receive sensor signals from one or more feedback sensors 218. As described below in connection with FIG. 7, system controller 202 can include any suitable computing devices for controlling the systems and/or processes described herein for forming metallization for solar cells, such as a processor, a computer, a data processing device, or any suitable combination of such devices.

In some embodiments, control system 200 can include a first laser controller 204 that controls properties and/or operation of first laser 102. For example, first laser controller can control a pulse length of pulses 104 emitted by first laser 102, a pulse timing at which pulses 104 are emitted by first laser 102, a power of pulses emitted by first laser 102, and/or any other properties and/or operations of first laser 102. In some embodiments, first laser controller 204 can be included in first laser 102 as built in control circuitry and may not be a separate controller. Additionally, first laser controller 204 can include any suitable circuitry and/or instructions for controlling properties and/or operations of first laser 102, such as a hardware processor, software, firmware, memory, and/or any other suitable circuitry for controlling properties and/or operation of first laser 102. Additionally or alternatively, control signals can be communicated to first laser controller 204 and/or first laser 102 from system controller 202, which can, in some embodiments, directly control operations and/or properties of first laser 102. In some embodiments, certain properties of first laser 102 can be fixed (e.g., by the manufacturing process used to manufacture first laser 102).

In some embodiments, control system 200 can include first laser focus controller 206 that controls a distance at which pulses 104 emitted by first laser 102 are focused. For example, first laser focus controller 206 can control first optics 110 to control a depth beneath the surface of rotating target 106 at which pulses 104 are focused.

In some embodiments, control system 200 can include a second laser controller 208 that controls properties and/or operation of second laser 114. For example, second laser controller can control whether beam 116 is emitted by second laser 114, a frequency of light emitted by second laser 114, a power of beam 116 emitted by second laser 114, and/or any other properties and/or operations of second laser 114. In some embodiments, second laser controller 208 can be included in second laser 114 as built in control circuitry and may not be a separate controller. Additionally, second laser controller 208 can include any suitable circuitry and/or instructions for controlling properties and/or operations of second laser 208, such as a hardware processor, software, firmware, memory, and/or any other suitable circuitry for controlling properties and/or operation of second laser 114. Additionally or alternatively, control signals can be communicated to second laser controller 208 and/or second laser 114 from system controller 202, which can, in some embodiments, directly control operations and/or properties of second laser 114. In some embodiments, certain properties of second laser 114 can be fixed (e.g., by the manufacturing process used to manufacture second laser 114).

In some embodiments, control system 200 can include a flying mirror controller 210 that controls an angle at which flying mirror 120 is positioned with respect to a direction from which second laser 114 emits beam 116. For example, flying mirror controller 210 can include any suitable hardware and/or software for precisely controlling an angle of flying mirror 120, such as stepper motors, actuators, linear actuators, microelectromechanical systems (MEMS).

In some embodiments, control system 200 can include second laser focus controller 212 that controls a distance at which beam 116 emitted by second laser 114 is focused. For example, second laser focus controller 212 can control second optics 118 to control a size and/or shape of elliptical spot 122 at the surface of substrate 112.

In some embodiments, control system 200 can include a spindle controller 214 that controls a rotation speed and/or position of a spindle that rotates rotating target 106. Spindle controller 214 can control, for example, a rotational speed of rotating target 106. As another example, spindle controller can control a positioning of the spindle that rotates rotating target 106, such as by controlling a height of rotating target 106 with respect to a surface of substrate 112 and/or the table for moving substrate 112, and/or by controlling a distance between rotating target 106 and first optics 110. In some embodiments, as material is ablated away from rotating target 106, spindle controller 214 can be used to control a speed of rotation of rotating target 106 (e.g., at any suitable speed up to limit of, for example, 8,000 RPM, 10,000 RPM, etc.) to ensure that a linear speed at an outer edge of a rotating target remains substantially constant and/or within a range of tolerable values to maintain a suitable shape for plume 108. Additionally or alternatively, as material is ablated away from rotating target 106, spindle controller 214 can be used to control a position of rotating target 106 with respect to pulses 104 to ensure that a suitable shape and/or positioning of plume 108 is maintained.

In some embodiments, control system 200 can include a substrate movement controller 216 that controls movement of substrate 112 with respect to the rest of system 100. For example, substrate movement controller 216 can control moving table or other movable platform to which substrate 112 is affixed. In some embodiments, substrate movement controller 216 can cause substrate 112 to move in relation to rotating target 206 such that line 124 is deposited in a substantially consistent manner. For example, as line 124 is deposited, substrate movement controller 216 can advance the substrate under rotating target 106 at a constant or varying speed. In a more particular example, depending on the desired properties of line 124 and/or other system properties, substrate movement controller 216 can cause substrate 112 to move under rotating target 106 at a constant speed while material is ablated from rotating target 106 by first laser 102. In such an example, the speed can be controlled such that substrate 112 can be moved at the constant speed without pausing or backtracking. In another more particular example, substrate movement controller 216 can cause substrate 112 to move under rotating target 106 in a stepwise or other non-constant manner. In such an example, substrate 112 can be moved under the control of substrate movement controller 216 to a position where a first portion of material from rotating target 106 is ablated onto substrate 112 (e.g., using one or more pulses 104), and then moved such that a second portion of material can be ablated from rotating target 106, and so on until line 124 is adequately formed.

In some embodiments, control system 200 can include one or more feedback sensors 218 which can measure one or more properties and/or characteristics of system 100 to be used by system controller 202 and/or any of controllers 204-216 in controlling operation of the system. The feedback sensors can measure any suitable properties and/or characteristics. For example, feedback sensors 218 can include one or more sensors that measure a temperature, pressure, and/or composition of the atmosphere in which system 100 is operating. As another example, feedback sensors 218 can include one or more sensors that measure and/or indicate a temperature of rotating target 106 at one or more locations, which may be an internal and/or surface temperature. As yet another example, feedback sensors 218 can include one or more sensors that measure a location and/or focusing distance of first optics 110 and/or second optics 118. As still another example, feedback sensors 218 can include one or more sensors that measure a rotational speed and/or dimensions of rotating target 106, from which a linear speed at the surface can be calculated, for example. As a further example, feedback sensors 218 can include one or more sensors that measure the temperature of one or more locations of substrate 112. As another further example, feedback sensors 218 can include one or more sensors that measure the shape and/or composition (e.g., distribution and/or sizes of clusters of ablated material) of plume 108, such one or more machine vision camera, one or more interferometers, and/or any other suitable sensors for measuring the shape and/or composition of plume 108. Additionally, any other suitable sensors or any combination of sensors can provide information to system controller 202 and/or controllers 204-216, including no sensors. For example, system 100 can be run without feedback according to an algorithm that uses an initial state of system 100 as an input to begin a process for forming metallization for solar cells.

In some embodiments, system controller 202 and/or controllers 204-216 can use information from feedback sensors to control operation of system 100 for forming metallization for solar cells. For example, as material is ablated from rotating target 106, control system 200 can measure the shape and/or composition of plume 108, characteristics of line 124, a rotational speed and/or size of rotating target 106, a temperature of rotating spindle 106, and/or any other characteristics related to system 100, and can use these measurements to ensure that line 124 is deposited within a tolerance of a specified size and/or shape.

FIG. 3 shows an example 300 of plume 108 being formed when at least one pulse 104 impinges upon a surface of rotating target 106 in accordance with some embodiments of the disclosed subject matter. As shown in FIG. 3, pulse 104 can impinge on a surface of rotating target 106, and at least a portion of the radiation (e.g., light) in pulse 104 can be absorbed by rotating target 106. Absorption of this radiation can lead to ionization of material in rotating target 106 at a location 302 below the surface, followed by explosive ablation of plume 108.

As shown in FIG. 3, plume 108 can include relatively large clusters 304 and relatively small clusters 306. In some embodiments, large clusters 304 can be material ablated from rotating target 106 with a relatively large size, such as one the order of about one hundred (100) nanometers (nm) to one (1) micrometer (μm). On the other hand, small clusters 306 can be material ablated from rotating target 106 with a relatively small size, such as smaller than 100 nm. Additionally, a certain amount of material ablated from 302 evaporates and is not included in plume 108. In general, if the target is a higher temperature, more material is evaporated during ablation. Using short pulses can reduce the amount of heating of the target and can reduce the amount of material lost to evaporation. It is recognized that a cutoff in size between large clusters 304 and small clusters 306 is described herein as being at 100 nm, while in reality the distribution of sizes may be more gradual with intermixing of large and small clusters near a border region of plume 108. Small clusters 306 can include individual atoms of material, ions of material, and/or clusters that are relatively small in size. The size of clusters ablated due to the impingement of pulse 104 can be controlled based at least on the duration of pulse 104, the total energy of pulse 104, and the temperature of rotating target 106. For example, a shorter duration pulse 104 can result in a smaller share of the material ablated from location 302 being evaporated. Additionally, in some embodiments, a higher power pulse 104 can result in the average size of ablated clusters being larger than the size of clusters ablated due to a lower powered pulse 104.

In some embodiments, a distribution of large clusters 304 and small clusters 306 within plume 108 can depend on a linear velocity of rotating target at location 302 which provides a tangential velocity component 308 to large clusters 304 and small clusters 306, and the energy imparted by the explosive ablation of the clusters which provides a normal velocity component 310. Note that the average velocity imparted by the explosive ablation is normal to the surface of rotating target 106, but it is recognized that individual clusters can be ejected at an angle that deviates from normal. However, for simplicity of explanation, it is assumed that most of the clusters are expelled with a component that is substantially normal to the surface of rotating target 106. The direction at which each cluster moves away from the surface of rotating target 106 is generally determined by adding tangential velocity component 308 and normal velocity component 310 of each cluster. Small clusters 306 generally have a higher normal velocity component because of the lower mass associated with their smaller size, and thus are ejected in a direction closer to the direction of pulse 104 than larger clusters, which have a smaller normal velocity component. Furthermore, large clusters 304 lose heat imparted by laser pulse 104 and the explosive ablation more slowly than small clusters due to the larger ratio between the large clusters' mass and surface area. That is, because the small clusters have a larger surface area in comparison to their mass, the smaller clusters tend to dissipate heat faster than the large clusters. Additionally, in some embodiments, the shape and/or distribution of plume 108 can be controlled using one or more techniques. For example, an electric field and/or a magnetic field can be applied to plume 108, which can control a direction of travel of any charged materials (e.g., ions) and/or dipole materials. As another example, the atmosphere can be controlled to provide more atmospheric resistance which can affect small clusters 306 more than large clusters 304. As yet another example, directional atmospheric pressure (e.g., air flow) can be applied to small clusters 306 and large clusters 304 to alter a path of the clusters to substrate 112. Due to the larger surface area of small clusters 306 in comparison to their mass, small clusters 306 are deflected more by the same pressure.

FIG. 4 shows an example 400 of various stages in a process for forming metallization for solar cells in accordance with some embodiments of the disclosed subject matter. As shown in FIG. 4, in some embodiments, a first stage can include ablating a dielectric 402 by aiming elliptical spot 122 at a location of substrate 112 at which line 124 is to be deposited. This first stage is illustrated in FIG. 4 as beam 404. As discussed above in connection with FIGS. 1 and 2, in some embodiments, flying mirror 120 can be used to control a location of elliptical spot 122 (e.g., a direction of beam 116) with respect substrate 112 and plume 108. In some embodiments, a power and/or a frequency of light emitted by second laser 114 can be controlled to provide more efficient ablation of dielectric 402 during the first stage. Additionally or alternatively, in some embodiments, the first stage can be performed using an additional laser to second laser 114, such as a laser that emits in the ultraviolet or blue portion of the spectrum. In some embodiments, the dielectric can be removed prior to substrate 112 being introduced to system 100 and the first stage can be omitted.

In some embodiments, a second stage can include heating an exposed surface 406 of substrate 112. For example, as elliptical spot is moved along substrate 112 with respect to plume 108, the surface 404 of substrate 112 can be heated after ablation of dielectric 402 is completed.

In some embodiments, a third stage can include heating clusters in plume 108 for deposition on surface 404 of substrate 112. As shown in FIG. 4, in some embodiments, plume 108 can deposit material in an area 408 on substrate 112, some of which can still be covered by dielectric. Heating clusters in plume 408 above the location on substrate 112 at which line 124 is to be deposited can help maintain the temperature of clusters that fall onto exposed surface 404 of substrate 112. In some embodiments, clusters that are not heated in the third stage by the second laser can fall onto the dielectric covering substrate 112, and can be removed. Additionally, in some embodiments, without heating by the second laser, the clusters in plume 108 that fall onto dielectric can lose enough heat to inhibit significantly damaging or becoming affixed to the dielectric. This third stage is illustrated in FIG. 4 as beam 410. In some embodiments, clusters that fall onto the dielectric can be removed (e.g., by being blown with pressurized gas (e.g., air) and/or using any other suitable techniques) for recycling and/or other suitable disposal.

In some embodiments, a fourth stage can include heating the deposited clusters of newly formed line 124. Heating in the fourth stage can cause the deposited material to melt together which can increase the conductivity of line 124. This fourth stage is illustrated in FIG. 4 as beam 412.

In some embodiments, any or all of the first through fourth stages can be repeated by moving elliptical spot 122 back and forth along a direction 414 as substrate 112 is moved under rotating target 106.

Although second laser 114 with flying mirror 120 is generally described herein as being used for each of the first through fourth stages, different lasers and/or other techniques can be used in addition to or in lieu of the second laser for any or all of the stages. For example, a separate laser can be used to ablate dielectric 402 at the first stage. As another example, different lasers can be used to heat the substrate, heat the clusters in plume 108, and/or heat the deposited clusters. As yet another example, the clusters in plume 108 can be heated using other techniques, such as well-known techniques for igniting argon (Ar) plasma near the surface of substrate during deposition of the clusters.

FIG. 5 shows an example 500 of a process for forming metallization for solar cells in accordance with some embodiments of the disclosed subject matter. In some embodiments, process 500 can begin, at 502, by receiving one or more specifications for a material or materials to deposit on a substrate, and can determine parameters for the system based on the specifications. In some embodiments, the specifications can include one or more material types to be deposited (e.g., copper, aluminum, nickel, silver, titanium, and/or any other suitable materials), an initial size of a target (e.g., a radius of the target, a thickness of the material on the target, etc.) including the one or more materials to be used in performing the deposit, and/or any other suitable characteristics of the target to be used. In some embodiments, the specifications can also include desired characteristics of a line (and/or any other suitable features) to be formed. The line characteristics can include a height and/or width of the line, an aspect ratio of the line, whether the line is to include layers of different material, and/or any other suitable characteristics of the line.

In some embodiments, process 500 can also determine parameters of the system at 502, which can include, for example: an initial speed at which to rotate the target (e.g., a speed to rotate the spindle arm); a power at which laser pulses 104 are to be emitted by first laser 102; a duration of laser pulses 104; a wavelength or wavelengths of light to use for laser pulses 104; a power at which beam 116 is to be emitted by second laser 114; a wavelength or wavelengths of light to use for beam 116; a pressure at which a chamber that includes system 100 is to be maintained; a composition of the atmosphere at which a chamber that includes system 100 is to be maintained (e.g., some materials may require replacing oxygen in the atmosphere with nitrogen or another case that does not cause the material to become unsuitable for use in a solar cell); and/or any other suitable parameters.

At 504, in some embodiments, process 500 can cause a substrate (e.g., substrate 112) on which the material is to be deposited (e.g., as line 124) to be positioned for receiving the deposited material (and/or any other suitable processing, such as ablating dielectric). In some embodiments, the substrate can be manually and/or automatically affixed to a platform for positioning the substrate (e.g., as described above in connection with FIGS. 1 and 2).

At 506, in some embodiments, process 500 can cause the spindle that controls rotation of the rotating target material (e.g., rotating target 106) to be rotated at the determined speed. For example, as described above, system controller 202 can cause spindle controller 214 to spin rotating target at a rotational speed determined at 502.

Additionally, in some embodiments, process 500 can control focus of first laser 102 (e.g., as described above in connection with system controller 202 and first focus controller 206 of FIG. 2), focus of second laser 114 (e.g., as described above in connection with system controller 202 and second focus controller 212 of FIG. 2), positioning of first laser 102 and/or second laser 114, and/or any other properties of system 100.

At 508, in some embodiments, process 500 can cause material to be ablated from the rotating target (e.g., rotating target 106) and deposited on the substrate (e.g., as line 124 on substrate 112). In some embodiments, the material can be ablated and deposited as described above in connection with FIGS. 1-4.

At 510, in some embodiments, process 500 can receive sensor feedback indicating current characteristics and/or operating parameters of the system (e.g., system 100), current characteristics of the rotating target (e.g., rotating target 106), properties of the plume being ablated from the rotating target (e.g., plume 108), a size of the rotating target, any temperature changes in the chamber, temperature changes of the target, temperature changes of the substrate, pressure changes, and/or any other suitable properties of the system and materials. For example, as described above in connection with FIG. 2, sensors 218 can gather information about these various properties of the system and its operations and can send such information to system controller 202 and/or controllers 204-216.

At 512, in some embodiments, process 500 can reevaluate the parameters of the system based on feedback received at 510. For example, if the size of the target has changed, process 500 can determine a new rotational speed at which to rotate the target, a new position at which to aim laser pulses 104, a new position for substrate 112 (e.g., based on the targets decreased size), and/or any other suitable new parameters. Similarly, if the shape and/or composition of plume 108 has changed and is unacceptable, process 500 can determine which parameters to change in order to correct the shape and/or composition of plume 108.

At 514, if any parameters have changed at 512, process 500 can control one or more subsystems based on the reevaluated parameters determined at 512. For example, as described above in connection with FIG. 2, system controller 202 and/or controllers 204-216 can control one or more subsystems of system 100 to change the system parameters to the reevaluated parameters. After changing the system parameters at 514, process 500 can return to 504 and position the substrate for additional deposit of material.

FIG. 6 shows an example 600 of a system for simultaneously forming multiple metallization fingers for solar cells in accordance with some embodiments of the disclosed subject matter. For example, in some embodiments, system 600 can be used to form fifty to eighty metal lines (e.g., fingers) on a substrate. As shown in FIG. 6, system 600 can be similar to system 100 described above in connection with FIG. 1, but can form multiple lines 124 simultaneously. In some embodiments, system 600 can include first laser 102, second laser 114, and rotating target 106, which can be used to deposit lines 124 on substrate 112. Additionally, in some embodiments, rotating target 106 in system 600 can be an elongated cylindrical target, and multiple pulses 610 can impinge along the length of rotating target 106.

In some embodiments, as shown in FIG. 6, to produce multiple pulses 610, a beam splitter 602 can be coupled to first laser 102, which can split an individual pulse into multiple pulse that can each be directed at rotating target 106. System 600 can also include, in some embodiments, individual first optics 606 for focusing each of the multiple pulses 610. First optics 606 can include any suitable optics for focusing a laser pulse emitted by first laser 102. In some embodiments, a power of first laser 102 can be increased in system 600 relative to system 100 to account for the decrease in the power of each of the multiple pulses due to the use of beam splitter 602.

In some embodiments, system 600 can include second laser 114, and multiple beams 612 can be used to perform any or all of the first through fourth stages described above in connection with FIG. 4. In some embodiments, as shown in FIG. 6, to produce multiple beams 612, a second beam splitter 604 can be coupled to second laser 114, which can split an individual beam into multiple beams that can each be directed at substrate 112. System 600 can also include, in some embodiments, individual second optics 608 for focusing each of the multiple beams 612. Second optics 608 can include any suitable optics for focusing a laser beam emitted by second laser 114. In some embodiments, a power of second laser 114 can be increased in system 600 relative to system 100 to account for the decrease in the power of each of the multiple beams due to the use of second beam splitter 604. In some embodiments, multiple laser and/or multiple beam splitters can be used in place of the single lasers with single beam splitters shown in FIG. 6.

FIG. 7 illustrates an example 700 of hardware that can be used to implement system controller 202 and/or any or all of controllers 204-216 depicted in FIG. 2 in accordance with some embodiments of the disclosed subject matter. Referring to FIG. 7, system controller 202 can include a hardware processor 712, a display 714, an input device 716, and memory 718, which can be interconnected. In some embodiments, memory 718 can include a storage device (such as a non-transitory computer-readable medium) for storing a computer program for controlling hardware processor 712.

In some embodiments, system controller 202 can be implemented as any of a general purpose device such as a computer or a special purpose device such as a client, a server, etc. Any of these general or special purpose devices can include any suitable components such as a hardware processor 712 (which can be a microprocessor, digital signal processor, a controller, etc.), memory 718, communication interfaces, display controllers, input devices, etc. For example, system controller 202 can be implemented as a personal computer, a laptop computer, a server computer, a mainframe computer, a game console, any other suitable computing device, or any suitable combination thereof.

In some embodiments, system controller 202 can communicate with other computing devices and/or controllers 204-216 using a communication network. The communications network can be any suitable computer network or combination of such networks including the Internet, an intranet, a wide-area network (WAN), a local-area network (LAN), a wireless network, a Wi-Fi network, a digital subscriber line (DSL) network, a frame relay network, an asynchronous transfer mode (ATM) network, a virtual private network (VPN), an intranet, etc. Communication links for communication over the communication network can be any communications links suitable for communicating data among system controller 202, controllers 204-216, and/or remote computing devices, such as network links, dial-up links, wireless links, hard-wired links, any other suitable communications links, or any suitable combination of such links.

Hardware processor 712 can use the computer program to execute the mechanisms described herein for forming metallization for solar cells. In some embodiments, hardware processor 712 can send and receive data through the communications links or any other communication links using, for example, a transmitter, a receiver, a transmitter/receiver, a transceiver, or any other suitable communication device. Display 714 can include a touchscreen, a flat panel display, a cathode ray tube display, a projector, a speaker or speakers, and/or any other suitable display and/or presentation devices. Input device 716 can be a computer keyboard, a computer mouse, a touchpad, a voice recognition circuit, a touchscreen, and/or any other suitable input device.

In some embodiments, the mechanisms described herein can include hardware, software, firmware, or any suitable combination thereof. For example, these mechanisms can encompass a computer program written in suitable programming language recognizable by system controller 202 and/or controllers 204-216. For example, these mechanisms can encompass a computer program that causes a processor (such as hardware processor 712) to execute the mechanisms described herein. For instance, these mechanisms can encompass a computer program written in a programming language recognizable by system controller 202 and/or controllers 204-216 that is executing the mechanisms (e.g., a program written in a programming language, such as, Java, C, Objective-C, C++, C#, JavaScript, Visual Basic, HTML, XML, ColdFusion, G-code, M-code, G&M-code, any other suitable approaches, or any suitable combination thereof).

In some embodiments, any suitable computer readable media can be used for storing instructions for performing the functions and/or processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

In some embodiments of the disclosed subject matter, the above described steps of the processes of FIGS. 1 and 3-6 can be executed or performed in any order or sequence not limited to the order and sequence shown and described in the figures. Also, some of the above steps of the processes of FIGS. 1 and 3-6 can be executed or performed substantially simultaneously where appropriate or in parallel to reduce latency and processing times. Furthermore, it should be noted that FIGS. 1 and 3-6 are provided as examples only. At least some of the steps shown in these figures may be performed in a different order than represented, performed concurrently, or omitted.

The provision of the examples described herein (as well as clauses phrased as “such as,” “e.g.,” “including,” and the like) should not be interpreted as limiting the claimed subject matter to the specific examples; rather, the examples are intended to illustrate only some of many possible aspects. It should also be noted that, as used herein, the term mechanism can encompass hardware, software, firmware, or any suitable combination thereof.

Accordingly, methods, systems, and media for forming metallization for solar cells are provided.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways.

What is claimed is:

1. A system for forming metallization on a substrate, the system comprising:
a first laser;
a second laser; and
at least one hardware processor programmed to:
cause a rotating target to rotate at a predetermined speed;
cause the first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target;
causing a continuous laser beam emitted by the second laser to be aimed toward a first location on the surface of the substrate such that the continuous laser beam passes through the plume of ablated material and heats clusters in the plume of ablated material prior to the clusters landing on the surface of the substrate; and
causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

2. The system of claim 1, further comprising:
a moving platform to which the substrate is secured;
wherein the at least one hardware processor is further programmed to:
cause the moving platform to advance the substrate along a direction of travel of the laser pulse.

3. The system of claim 1, wherein the first laser is a Nd:YAG laser and the laser pulse includes 355 nm light.

4. The system of claim 1, wherein the rotating target includes copper.

5. The system of claim 1, wherein the continuous laser beam includes 1064 nm light.

6. The system of claim 1, further comprising:
a rotatable mirror; and
wherein the at least one hardware processor is programmed to cause the rotatable mirror to rotate between a first position that causes the continuous laser beam to be aimed at the first location and a second position that causes the continuous laser beam to be aimed at the second location.

7. The system of claim 1, wherein the at least one hardware processor is further programmed to:
causing the continuous laser beam emitted by the second laser to be aimed toward a third location on the surface of the substrate having a dielectric layer such that the dielectric layer is removed prior to ablated material being deposited at the third location; and
causing the continuous laser beam emitted by the second laser to be aimed toward a fourth location on the surface of the substrate where the dielectric layer has been removed and prior to ablated material being deposited at the fourth location such that surface of the substrate is heated at the fourth location prior to ablated material being deposited at the fourth location.

8. The system of claim 1, wherein the clusters that are deposited on the surface of the substrate include clusters that are between 100 nanometer and 1 micrometer in size.

9. A method for forming metallization on a substrate, the method comprising:
causing a rotating target to rotate at a predetermined speed;
causing a first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target;
causing a continuous laser beam emitted by a second laser to be aimed toward a first location on the surface of the substrate such that the continuous laser beam passes through the plume of ablated material and heats clusters in the plume of ablated material prior to the clusters landing on the surface of the substrate; and
causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

10. The method of claim 9, further comprising causing a moving platform to which the substrate is secured to advance the substrate along a direction of travel of the laser pulse.

11. The method of claim 9, wherein the first laser is a Nd:YAG laser and the laser pulse includes 355 nm light.

12. The method of claim 9, wherein the rotating target includes copper.

13. The method of claim 9, wherein the continuous laser beam includes 1064 nm light.

14. The method of claim 9, further comprising causing a rotatable mirror to rotate between a first position that causes the continuous laser beam to be aimed at the first location and a second position that causes the continuous laser beam to be aimed at the second location.

15. The method of claim 9, further comprising:
causing the continuous laser beam emitted by the second laser to be aimed toward a third location on the surface of the substrate having a dielectric layer such that the dielectric layer is removed prior to ablated material being deposited at the third location; and
causing the continuous laser beam emitted by the second laser to be aimed toward a fourth location on the surface of the substrate where the dielectric layer has been removed and prior to ablated material being deposited at the fourth location such that surface of the substrate is heated at the fourth location prior to ablated material being deposited at the fourth location.

16. The method of claim 9, wherein the clusters that are deposited on the surface of the substrate include clusters that are between 100 nanometer and 1 micrometer in size.

17. A non-transitory computer-readable medium containing computer executable instructions that, when executed by a processor, cause the processor to perform a method for forming metallization on a substrate, the method comprising:
causing a rotating target to rotate at a predetermined speed;
causing a first laser to emit a laser pulse that impinges the rotating target at a first location, wherein upon impinging the rotating target the laser pulse causes a plume of material to be ablated from the rotating target toward a surface of a substrate disposed below the rotating target, wherein a surface of the substrate is substantially parallel to the path of the laser pulse just prior to impinging the rotating target;
causing a continuous laser beam emitted by a second laser to be aimed toward a first location on the surface of the substrate such that the continuous laser beam passes through the plume of ablated material and heats clusters in the plume of ablated material prior to the clusters landing on the surface of the substrate; and
causing the continuous laser beam emitted by the second laser to be aimed toward a second location on the surface of the substrate having deposited clusters from the plume of ablated material that have landed on the surface of the substrate such that the continuous laser beam further heats the deposited clusters together forming a metallization line on the surface of the substrate.

18. The non-transitory computer-readable medium of claim 17, wherein the method further comprises causing a moving platform to which the substrate is secured to advance the substrate along a direction of travel of the laser pulse.

19. The non-transitory computer-readable medium of claim 17, wherein the first laser is a Nd:YAG laser and the laser pulse includes 355 nm light.

20. The non-transitory computer-readable medium of claim 17, wherein the rotating target includes copper.

21. The non-transitory computer-readable medium of claim 17, wherein the continuous laser beam includes 1064 nm light.

22. The non-transitory computer-readable medium of claim 17, wherein the method further comprises causing a rotatable mirror to rotate between a first position that causes the continuous laser beam to be aimed at the first location and a second position that causes the continuous laser beam to be aimed at the second location.

23. The non-transitory computer-readable medium of claim 17, wherein the method further comprises:
causing the continuous laser beam emitted by the second laser to be aimed toward a third location on the surface of the substrate having a dielectric layer such that the dielectric layer is removed prior to ablated material being deposited at the third location; and
causing the continuous laser beam emitted by the second laser to be aimed toward a fourth location on the surface of the substrate where the dielectric layer has been removed and prior to ablated material being deposited at the fourth location such that surface of the substrate is heated at the fourth location prior to ablated material being deposited at the fourth location.

24. The non-transitory computer-readable medium of claim 17, wherein the clusters that are deposited on the surface of the substrate include clusters that are between 100 nanometer and 1 micrometer in size.
